(19) United States
(12) Patent Application Publication
(10) Pub. No.: US 2016/0049187 A1
(43) Pub. Date: Feb. 18, 2016

(54) SEMICONDUCTOR DEVICE

(71) Applicant: KABUSHIKI KAISHA TOSHIBA, Tokyo (JP)

(72) Inventor: Kanna ADACHI, Chigasaki Kanagawa (JP)

(73) Assignee: KABUSHIKI KAISHA TOSHIBA, Tokyo (JP)

(21) Appl. No.: 14/550,526

(22) Filed: Nov. 21, 2014

(30) Foreign Application Priority Data
Aug. 12, 2014 (JP) 2014-164494

(51) Int. Cl. G11C 11/412; G11C 7/10; G11C 5/06; H01L 27/11; H01L 29/08; G11C 11/417; G11C 7/12

(52) U.S. Cl. CPC G11C 11/412; G11C 11/417; G11C 7/1096; G11C 7/12; H01L 27/1104; H01L 29/0847; G11C 5/063

(57) ABSTRACT

In one embodiment, gate conductors include a pair of first portions and a pair of second portions. First and second load transistors each includes source and drain regions having different conductivity types and sandwiching one or the other of the first portions, a diffusion region of a first conductivity type corresponding to the drain region being between the first portions. First and second driver transistors each includes source and drain regions having different conductivity types and sandwiching the one or the other of the first portions, a diffusion region of the first conductivity type corresponding to the source region being between the first portions. First and second transfer transistors each includes source and drain regions having different conductivity types and sandwiching one or the other of the second portions, a diffusion region of the first conductivity type corresponding to the source region being between the second portions.

### CROSS REFERENCE TO RELATED APPLICATION

This application is based upon and claims the benefit of priority from the prior Japanese Patent Application No. 2014-164494, filed on Aug. 12, 2014, the entire contents of which are incorporated herein by reference.

### FIELD

Embodiments described herein relate to a semiconductor device.

### BACKGROUND

High performance of a static random access memory (SRAM) has been realized by shrinking MISFETs in SRAM cells. However, the shrinkage of the MISFETs makes it difficult to suppress the short channel effect of the MISFETs, and makes it difficult to reduce power consumption of the SRAM. Therefore, it is investigated to form the SRAM cells with tunnel transistors which are suitable for low power consumption of a semiconductor device.

A MISFET includes source and drain regions of the same conductivity type, whereas a tunnel transistor includes source and drain regions of different conductivity types. Therefore, if the cell layout of the SRAM including the MISFETs is applied to the SRAM including the tunnel transistors without any change, p-type diffusion regions and n-type diffusion regions for the source and drain regions are complexly disposed on a substrate. As a result, lithography for forming the source and drain regions may become difficult, and the characteristics of the tunnel transistors may suffer variation.

### BRIEF DESCRIPTION OF THE DRAWINGS

FIG. 1 is a circuit diagram illustrating a structure of a semiconductor device of a first embodiment;

FIGS. 2A to 2C are plan views illustrating the structure of the semiconductor device of the first embodiment;

FIGS. 3A to 3C are cross-sectional views illustrating structures of transistors of the first embodiment;

FIG. 4 is a graph for explaining operation of first and second transfer transistors of the first embodiment;

FIG. 5 is a plan view illustrating a structure of a semiconductor device of a first comparative example of the first embodiment; and

FIG. 6 is a plan view illustrating a structure of a semiconductor device of a second comparative example of the first embodiment.

### DETAILED DESCRIPTION

Embodiments will now be explained with reference to the accompanying drawings.

In one embodiment, a semiconductor device includes a substrate, and a plurality of gate conductors disposed above the substrate and including a pair of first portions and a pair of second portions. The device further includes a first load transistor which includes source and drain regions having different conductivity types and disposed to sandwich one of the pair of first portions, wherein a diffusion region of a first conductivity type corresponding to the drain region is disposed between the pair of first portions. The device further includes a second load transistor which includes source and drain regions having different conductivity types and disposed to sandwich the other of the pair of first portions, wherein a diffusion region of the first conductivity type corresponding to the drain region is disposed between the pair of first portions. The device further includes a first driver transistor which includes source and drain regions having different conductivity types and disposed to sandwich the one of the pair of first portions, wherein a diffusion region of the first conductivity type corresponding to the source region is disposed between the pair of first portions. The device further includes a second driver transistor which includes source and drain regions having different conductivity types and disposed to sandwich the other of the pair of first portions, wherein a diffusion region of the first conductivity type corresponding to the source region is disposed between the pair of first portions. The device further includes a first transfer transistor which includes source and drain regions having different conductivity types and disposed to sandwich one of the pair of second portions, wherein a diffusion region of the first conductivity type corresponding to the source region is disposed between the pair of second portions. The device further includes a second transfer transistor which includes source and drain regions having different conductivity types and disposed to sandwich the other of the pair of second portions, wherein a diffusion region of the first conductivity type corresponding to the source region is disposed between the pair of second portions.

### First Embodiment

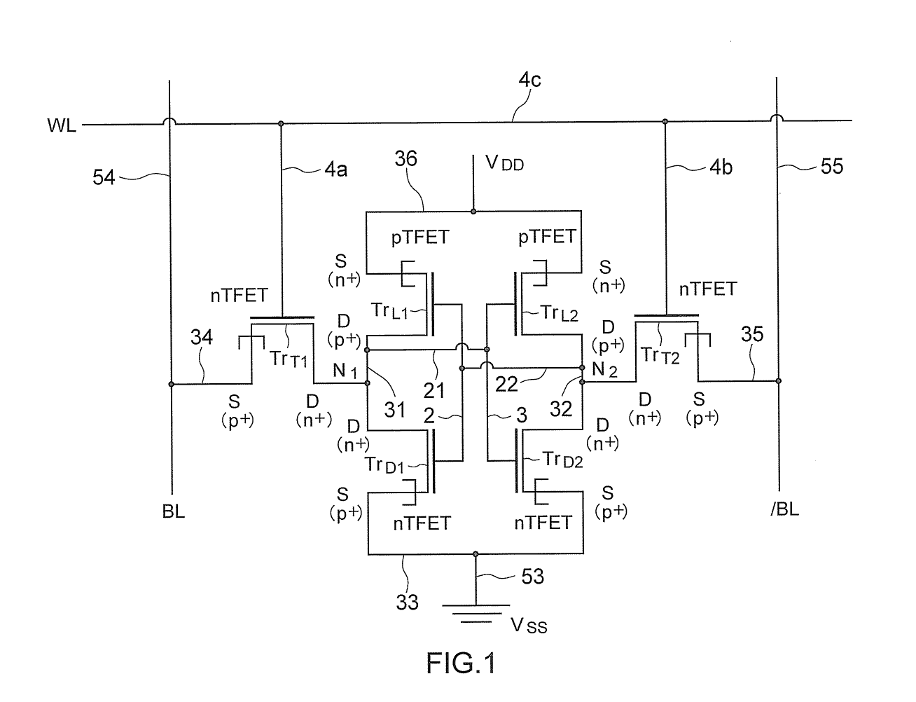

FIG. 1 is a circuit diagram illustrating a structure of a semiconductor device of a first embodiment. The semiconductor device in FIG. 1 includes an SRAM. FIG. 1 illustrates a SRAM cell formed by six tunnel transistors (TFETs).

The semiconductor device in FIG. 1 includes, as components of the SRAM cell, first and second load transistors Tr_{L1} and Tr_{L2} which are p-type TFETs, first and second driver transistors Tr_{D1} and Tr_{D2} which are n-type TFETs, and first and second transfer transistors Tr_{T1} and Tr_{T2} which are n-type TFETs. FIG. 1 further illustrates a word line WL, bit lines BL and /BL, and storage nodes N₁ and N₂ of the SRAM cell.

The source of the first load transistor Tr_{L1} is connected to a power supply line V_{DD}. The source of the first driver transistor Tr_{D1} is connected to a ground line V_{SS}. The drain of the first load transistor Tr_{L1} is connected to the drain of the first driver transistor Tr_{D1}. The gate of the first load transistor Tr_{L1} is connected to the gate of the first driver transistor Tr_{D1}. Accordingly, the first load transistor Tr_{L1} and the first driver transistor Tr_{D1} form an inverter.

The source of the second load transistor Tr_{L2} is connected to the power supply line V_{DD}. The source of the second driver transistor Tr_{D2} is connected to the ground line V_{SS}. The drain of the second load transistor Tr_{L2} is connected to the drain of the second driver transistor Tr_{D2}. The gate of the second load transistor Tr_{L2} is connected to the gate of the second driver transistor Tr_{D2}. Accordingly, the second load transistor Tr_{L2} and the second driver transistor Tr_{D2} form an inverter.

The drain of the first load transistor Tr_{L1} and the drain of the first driver transistor Tr_{D1} are connected to the gate of the second load transistor Tr_{L2} and the gate of the second driver transistor Tr_{D2}. The drain of the second load transistor Tr_{L2} and the drain of the second driver transistor Tr_{D2} are connected to the gate of the first load transistor Tr_{L1} and the gate of the first driver transistor Tr_{D1}. Accordingly, the first and second load transistors Tr_{L1} and Tr_{L2} and the first and second driver transistors Tr_{D1} and Tr_{D2} form a flip-flop.

The storage node N₁ is located at the connection portion of the drain of the first load transistor Tr_{L1} and the drain of the first driver transistor Tr_{D1}. The storage node N₂ is located at the connection portion of the drain of the second load transistor Tr_{L2} and the drain of the second driver transistor Tr_{D2}. The storage nodes N₁ and N₂ correspond to output terminals of the flip-flop.

The first transfer transistor Tr_{T1} is used for electrically connecting the storage node N₁ to the bit line BL. The gate of the first transfer transistor Tr_{T1} is connected to the word line WL. The source of the first transfer transistor Tr_{T1} is connected to the bit line BL. The drain of the first transfer transistor Tr_{T1} is connected to the drain of the first load transistor Tr_{L1} and the drain of the first driver transistor Tr_{D1}.

The second transfer transistor Tr_{T2} is used for electrically connecting the storage node N₂ to the bit line /BL. The gate of the second transfer transistor Tr_{T2} is connected to the word line WL. The source of the second transfer transistor Tr_{T2} is connected to the bit line /BL. The drain of the second transfer transistor Tr_{T2} is connected to the drain of the second load transistor Tr_{L2} and the drain of the second driver transistor Tr_{D2}.

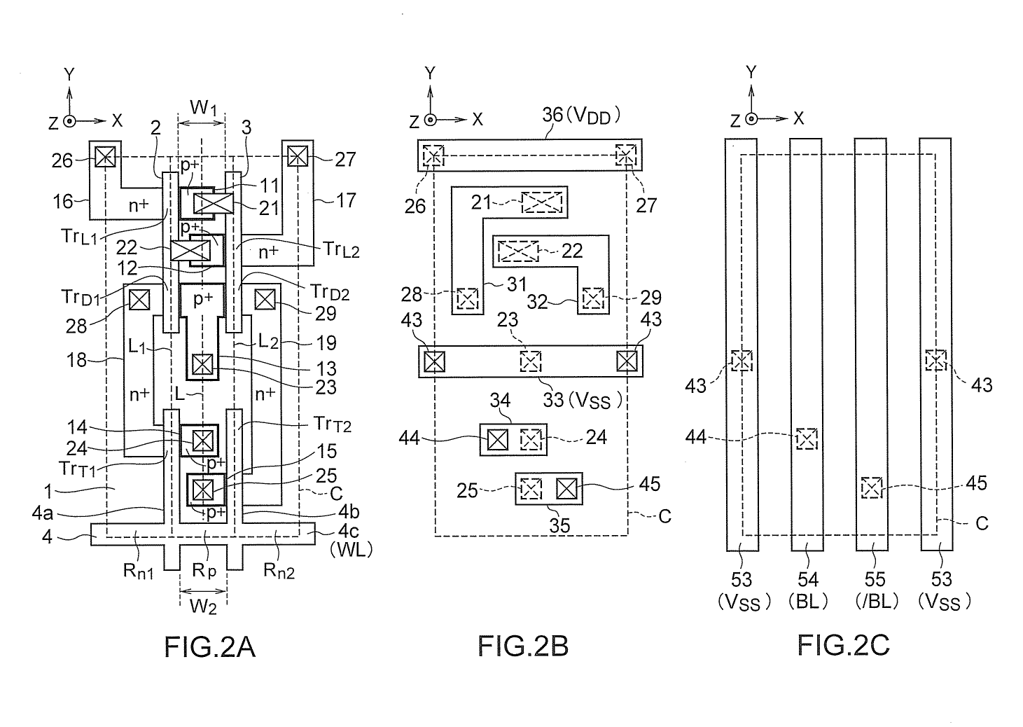

Details of signs 2, 3, . . . , 54 and 55 are described with reference to FIGS. 2A to 2C.

FIGS. 2A to 2C are plan views illustrating the structure of the semiconductor device of the first embodiment. FIGS. 2A to 2C illustrate a SRAM cell C similarly to FIG. 1. FIGS. 2A, 2B and 2C respectively illustrate a gate conductor layer, a first interconnect layer and a second interconnect layer of the semiconductor device of the present embodiment.

The semiconductor device of the present embodiment includes a substrate 1, a first gate conductor 2, a second gate conductor 3, and a third gate conductor 4 including a first conductor portion 4a, a second conductor portion 4b and a third conductor portion 4c. The first to third gate conductors 2 to 4 are examples of a plurality of gate conductors. The first and second gate conductors 2 and 3 are examples of a pair of first portions. The first and second conductor portions 4a and 4b are examples of a pair of second portions. The third conductor portion 4c is an example of a third portion.

The semiconductor device of the present embodiment further includes first to ninth diffusion regions 11 to 19, first to ninth contact plugs 21 to 29, first to sixth interconnects 31 to 36, first to third via plugs 43 to 45, and seventh to ninth interconnects 53 to 55. The first to fifth diffusion regions 11 to 15 are p⁺-type diffusion regions, and are examples of diffusion regions of a first conductivity type. The sixth to ninth diffusion regions 16 to 19 are n⁺-type diffusion regions, and are examples of diffusion regions of a second conductivity type.

[Substrate 1]

An example of the substrate 1 is a semiconductor substrate such as a silicon substrate. FIGS. 2A to 2C illustrate an X-direction and a Y-direction which are parallel to the surface of the substrate 1 and perpendicular to each other, and a Z-direction perpendicular to the surface of the substrate 1. The Y-direction is an example of a first direction parallel to the surface of the substrate 1. The X-direction is an example of a second direction perpendicular to the first direction.

In this specification, the +Z-direction is regarded as an upward direction and the −Z-direction is regarded as a downward direction. For example, the positional relation between the substrate 1 and the gate conductors 2 to 4 is expressed as that the substrate 1 is located below the gate conductors 2 to 4. The −Z-direction in the present embodiment may coincide with the direction of gravity or may not coincide with the direction of gravity.

[Gate Conductors 2 to 4]

The first to third gate conductors 2 to 4 are formed on the substrate 1 via unshown gate insulators. Examples of the gate insulators are silicon oxides. Examples of the first to third gate conductors 2 to 4 are polysilicon layers.

The first and second gate conductors 2 and 3 extend in the Y-direction and are adjacent to each other in the X-direction. Sign W₁ designates a width between the first and second gate conductors 2 and 3. The first gate conductor 2 functions as gate electrodes of the first load transistor Tr_{L1} and the first driver transistor Tr_{D1}. The second gate conductor 3 functions as gate electrodes of the second load transistor Tr_{L2} and the second driver transistor Tr_{D2}.

The first and second conductor portions 4a and 4b of the third gate conductor 4 extend in the Y-direction and are adjacent to each other in the X-direction. Sign W₂ designates a width between the first and second conductor portions 4a and 4b. The first conductor portion 4a functions as a gate electrode of the first transfer transistor Tr_{T1}. The second conductor portion 4b functions as a gate electrode of the second transfer transistor Tr_{T2}.

The third conductor portion 4c of the third gate conductor 4 extends in the X-direction, and is electrically connected to the first and second conductor portions 4a and 4b. The third conductor portion 4c functions as the word line WL.

In the present embodiment, the width W₁ is set to be substantially equal to the width W₂ (W₁=W₂). Moreover, the first gate conductor 2 and the first conductor portion 4a of the present embodiment have substantially the same line width and are disposed on a same straight line L₁ extending in the Y-direction. Moreover, the second gate conductor 3 and the second conductor portion 4b of the present embodiment have substantially the same line width and are disposed on a same straight line L₂ extending in the Y-direction. For example, such a structure has an advantage that lithography for forming the gate conductors 2 to 4 is readily performed.

[Diffusion Regions 11 to 19]

The first to ninth diffusion regions 11 to 19 are formed in the substrate 1. Each of the first to ninth diffusion regions 11 to 19 functions as a source region or a drain region of a TFET.

The first diffusion region 11 and the sixth diffusion region 16 correspond to a drain region and a source region of the first load transistor Tr_{L1}, respectively. The first diffusion region 11 and the sixth diffusion region 16 are disposed to sandwich the first gate conductor 2. The first diffusion region 11 is disposed in a region between the first and second gate conductors 2 and 3, and the sixth diffusion region 16 is disposed outside this region. The sixth diffusion region 16 is shared by the SRAM cell C and its adjacent SRAM cell.

The second diffusion region 12 and the seventh diffusion region 17 correspond to a drain region and a source region of the second load transistor Tr_{L2}, respectively. The second diffusion region 12 and the seventh diffusion region 17 are disposed to sandwich the second gate conductor 3. The second diffusion region 12 is disposed in a region between the first and second gate conductors 2 and 3, and the seventh diffusion region 17 is disposed outside this region. The seventh diffusion region 17 is shared by the SRAM cell C and its adjacent SRAM cell.

The drain regions of the first and second load transistors Tr_{L1} and Tr_{L2} of the present embodiment are separate diffusion regions which are the first and second diffusion regions 11 and 12. The first diffusion region 11 is disposed on the +Y-direction side of the second diffusion region 12. For example, such arrangement has an advantage that the width W₁ can be set narrow. The first diffusion region 11 may be disposed on the −Y-direction side of the second diffusion region 12.

The third diffusion region 13 corresponds to source regions of the first and second driver transistors Tr_{D1} and Tr_{D2}. The eighth diffusion region 18 and the ninth diffusion region 19 correspond to drain regions of the first and second driver transistors Tr_{D1} and Tr_{D2}, respectively. The third diffusion region 13 and the eighth diffusion region 18 are disposed to sandwich the first gate conductor 2. The third diffusion region 13 and the ninth diffusion region 19 are disposed to sandwich the second gate conductor 3. The third diffusion region 13 is disposed in a region between the first and second gate conductors 2 and 3, and the eighth and ninth diffusion regions 18 and 19 are disposed outside this region.

The source regions of the first and second driver transistors Tr_{D1} and Tr_{D2} of the present embodiment share the same diffusion region which is the third diffusion region 13. The third diffusion region 13 of the present embodiment has a shape extending in the Y-direction.

The fourth diffusion region 14 and the eighth diffusion region 18 correspond to a source region and a drain region of the first transfer transistor Tr_{T1}, respectively. The fourth diffusion region 14 and the eighth diffusion region 18 are disposed to sandwich the first conductor portion 4a. The fourth diffusion region 14 is disposed in a region between the first and second conductor portions 4a and 4b, and the eighth diffusion region 18 is disposed outside this region.

The fifth diffusion region 15 and the ninth diffusion region 19 correspond to a source region and a drain region of the second transfer transistor Tr_{T2}, respectively. The fifth diffusion region 15 and the ninth diffusion region 19 are disposed to sandwich the second conductor portion 4b. The fifth diffusion region 15 is disposed in a region between the first and second conductor portions 4a and 4b, and the ninth diffusion region 19 is disposed outside this region.

The source regions of the first and second transfer transistors Tr_{T1} and Tr_{T2} of the present embodiment are separate diffusion regions which are the fourth and fifth diffusion regions 14 and 15. The fourth diffusion region 14 is disposed on the +Y-direction side of the fifth diffusion region 15. For example, such arrangement has an advantage that the width W₂ can be set narrow. The fourth diffusion region 14 may be disposed on the −Y-direction side of the fifth diffusion region 15.

The drain regions of the first driver transistor Tr_{D1} and the first transfer transistor Tr_{T1} of the present embodiment share the same diffusion region which is the eighth diffusion region 18. The eighth diffusion region 18 of the present embodiment has a shape extending in the Y-direction.

The drain regions of the second driver transistor Tr_{D2} and the second transfer transistor Tr_{T2} of the present embodiment share the same diffusion region which is the ninth diffusion region 19. The ninth diffusion region 19 of the present embodiment has a shape extending in the Y-direction.

The first and second conductor portions 4a and 4b are respectively disposed on the ±X-direction sides of the fourth and fifth diffusion regions 14 and 15, whereas the third conductor portion 4c is disposed on the −Y-direction side of the fourth and fifth diffusion regions 14 and 15. In other words, the third conductor portion 4c is disposed on the opposite side to the third diffusion region 13 relative of the fourth and fifth diffusion regions 14 and 15. This is because the third conductor portion 4c is shared by the SRAM cell C and its adjacent SRAM cell in the −Y-direction.

Signs Rₚ, Rₙ₁ and Rₙ₂ designate regions in the SRAM cell C. The boundary of the region Rₚ and the region Rₙ₁ is a straight line L₁. The boundary of the region Rₚ and the region Rₙ₂ is a straight line L₂. The region Rₚ is located at a center portion in the SRAM cell C. The regions Rₙ₁ and Rₙ₂ are respectively located at end portions in the SRAM cell C in the ±X-directions. All of the regions Rₚ, Rₙ₁ and Rₙ₂ extend from an end portion in the +Y-direction to an end portion in the −Y-direction in the SRAM cell C.

As described above, the first, second and third diffusion regions 11, 12 and 13 are disposed between the first and second gate conductors 2 and 3, and the fourth and fifth diffusion regions 14 and 15 are disposed between the first and second conductor portions 4a and 4b.

Accordingly, the first to fifth diffusion regions 11 to 15 which are p-type regions are collectively disposed at the center portion in the SRAM cell C of the present embodiment. Specifically, the first to fifth diffusion regions 11 to 15 are disposed in the strip-shaped region Rₚ extending in the Y-direction. Therefore, all of the first to fifth diffusion regions 11 to 15 are disposed on the same straight line L extending in the Y-direction.

On the other hand, the sixth to ninth diffusion regions 16 to 19 which are n-type regions are disposed at the end portions in the SRAM cell C of the present embodiment. Specifically, the sixth and eighth diffusion regions 16 and 18 are disposed in the region Rₙ₁, and the seventh and ninth diffusion regions 17 and 19 are disposed in the region Rₙ₂. Therefore, the sixth and eighth diffusion regions 16 and 18 are disposed on the −X-direction side of the straight line L and the straight line L₁, in other words, on the −X-direction side of the strip-shaped region Rₚ. Moreover, the seventh and ninth diffusion regions 17 and 19 are disposed on the +X-direction side of the straight line L and the straight line L₂, in other words, on the +X-direction side of the strip-shaped region Rₚ.

The present embodiment makes it possible, by collectively disposing the first to fifth diffusion regions 11 to 15 at the center portion, to simplify the layout of the p-type regions and the n-type regions corresponding to the source/drain regions. Specifically, the first to fifth diffusion regions 11 to 15 which are the p-type regions, and the sixth to ninth diffusion regions 16 to 19 which are the n-type regions are respectively disposed in the region Rₚ and in the regions Rₙ₁ and Rₙ₂ which have simple strip shapes. Therefore, the present embodiment makes it possible to readily perform lithography for forming the source and drain regions, and to suppress variation in characteristics of the TFETs.

[Contact Plugs 21 to 29]

The first to ninth contact plugs 21 to 29 are formed on the first to ninth diffusion regions 11 to 19, respectively. The first to ninth contact plugs 21 to 29 electrically connect the first to ninth diffusion regions 11 to 19 to the first to sixth interconnects 31 to 36.

The first contact plug 21 is disposed on the first diffusion region 11 and on the second gate conductor 3. Thereby, the drain (first diffusion region 11) of the first load transistor Tr_{L1} is electrically connected to the gates (second gate conductor 3) of the second load transistor Tr_{L2} and the second driver transistor Tr_{D2}. (refer to FIG. 1).

The second contact plug 22 is disposed on the second diffusion region 12 and on the first gate conductor 2. Thereby, the drain (second diffusion region 12) of the second load transistor Tr_{L2} is electrically connected to the gates (first gate conductor 2) of the first load transistor Tr_{L1} and the first driver transistor Tr_{D1} (refer to FIG. 1).

[Interconnects 31 to 36]

The first to sixth interconnects 31 to 36 are formed on the first to sixth contact plugs 21 to 26, respectively. The sixth interconnect 36 is also formed on the seventh contact plug 27. The first and second interconnects 31 and 32 are also formed on the eighth and ninth contact plugs 28 and 29, respectively.

The first interconnect 31 is disposed on the first and eighth contact plugs 21 and 28. Thereby, the drain (first diffusion region 11) of the first load transistor Tr_{L1} is electrically connected to the drains (eighth diffusion region 18) of the first driver transistor Tr_{D1} and the first transfer transistor Tr_{T1} (refer to FIG. 1).

The second interconnect 32 is disposed on the second and ninth contact plugs 22 and 29. Thereby, the drain (second diffusion region 12) of the second load transistor Tr_{L2} is electrically connected to the drains (ninth diffusion region 19) of the second driver transistor Tr_{D2} and the second transfer transistor Tr_{T2} (refer to FIG. 1).

The third interconnect 33 is the ground line V_{SS}. The third interconnect 33 is disposed on the third contact plug 23. Thereby, the sources (third diffusion region 13) of the first and second driver transistors Tr_{D1} and Tr_{D2} are electrically connected to the ground line V_{SS} (refer to FIG. 1).

The sixth interconnect 36 is the power supply line V_{DD}. The sixth interconnect 36 is disposed on the sixth and seventh contact plugs 26 and 27. Thereby, the sources (sixth and seventh diffusion regions 16 and 17) of the first and second load transistors Tr_{L1} and Tr_{L2} are electrically connected to the power supply line V_{DD} (refer to FIG. 1).

[Via Plugs 43 to 45]

The first via plugs 43 are formed on the third interconnect 33. One of the first via plugs 43 is located at an end portion of the SRAM cell C in the +X-direction. The other of the first via plugs 43 is located at an end portion of the SRAM cell C in the −X-direction.

The second and third via plugs 44 and 45 are formed on the fourth and fifth interconnects 34 and 35, respectively.

[Interconnects 53 to 55]

The seventh interconnects 53 are formed on the first via plugs 43. The seventh interconnects 53 are the ground lines V_{SS}.

The eighth interconnect 54 is formed on the second via plug 44. The eighth interconnect 54 is the bit line BL. It electrically connects the source (fourth diffusion region 14) of the first transfer transistor Tr_{T1} to the bit line BL (refer to FIG. 1).

The ninth interconnect 55 is formed on the third via plug 45. The ninth interconnect 55 is the bit line /BL. It electrically connects the source (fifth diffusion region 15) of the second transfer transistor Tr_{T2} to the bit line /BL (refer to FIG. 1).

### (1) Transistors of First Embodiment

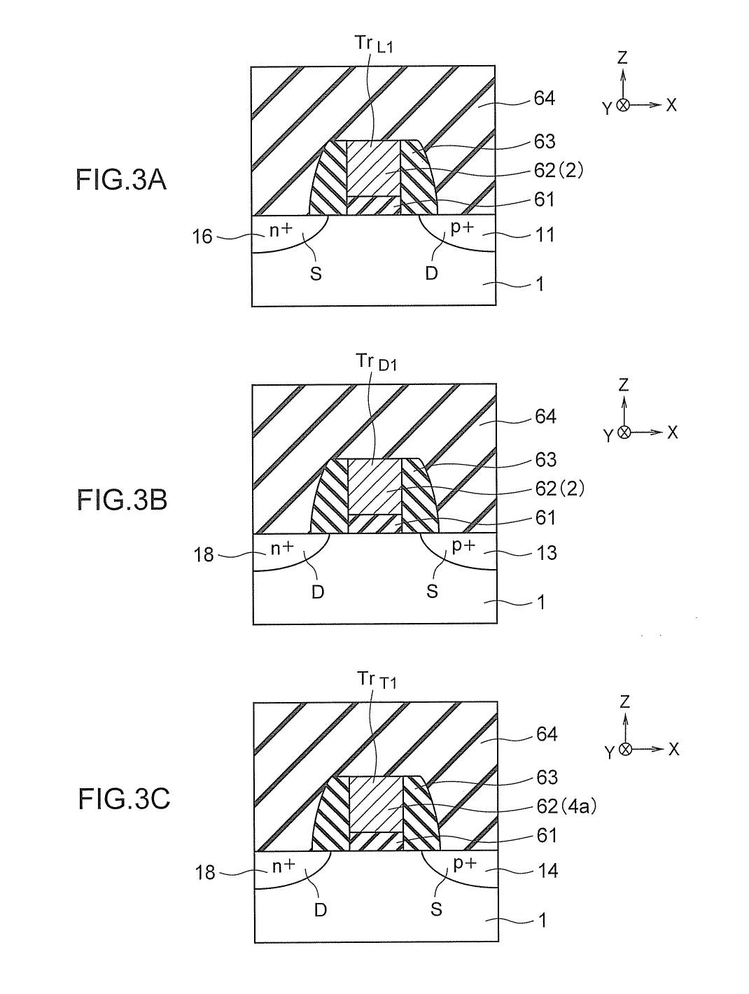

FIGS. 3A to 3C are cross-sectional views illustrating structures of the transistors of the first embodiment.

FIG. 3A illustrates a cross-section of the first load transistor Tr_{L1}. FIG. 3B illustrates a cross-section of the first driver transistor Tr_{D1}. FIG. 3C illustrates a cross-section of the first transfer transistor Tr_{T1}.

Each of these transistors includes a gate insulator 61 formed on the substrate 1, a gate electrode 62 formed on the gate insulator 61, and sidewall insulators 63 formed on the side faces of the gate electrode 62. These transistors are covered with an inter layer dielectric 64.

The gate electrode 62 (first gate conductor 2) of the first load transistor Tr_{L1} is sandwiched between the first diffusion region 11 and the sixth diffusion region 16 which have different conductivity types. The first diffusion region 11 functions as a drain region, and the sixth diffusion region 16 functions as a source region. The second load transistor Tr_{L2} has a similar structure to that of the first load transistor Tr_{L1}.

The gate electrode 62 (first gate conductor 2) of the first driver transistor Tr_{D1} is sandwiched between the third diffusion region 13 and the eighth diffusion region 18 which have the different conductivity types. The third diffusion region 13 functions as a source region, and the eighth diffusion region 18 functions as a drain region. The second driver transistor Tr_{D2} has a similar structure to that of the first driver transistor Tr_{D1}.

The gate electrode 62 (first conductor portion 4a) of the first transfer transistor Tr_{T1} is sandwiched between the fourth diffusion region 14 and the eighth diffusion region 18 which have the different conductivity types. The fourth diffusion region 14 functions as a source region, and the eighth diffusion region 18 functions as a drain region. The second transfer transistor Tr_{T2} has a similar structure to that of the first transfer transistor Tr_{T1}.

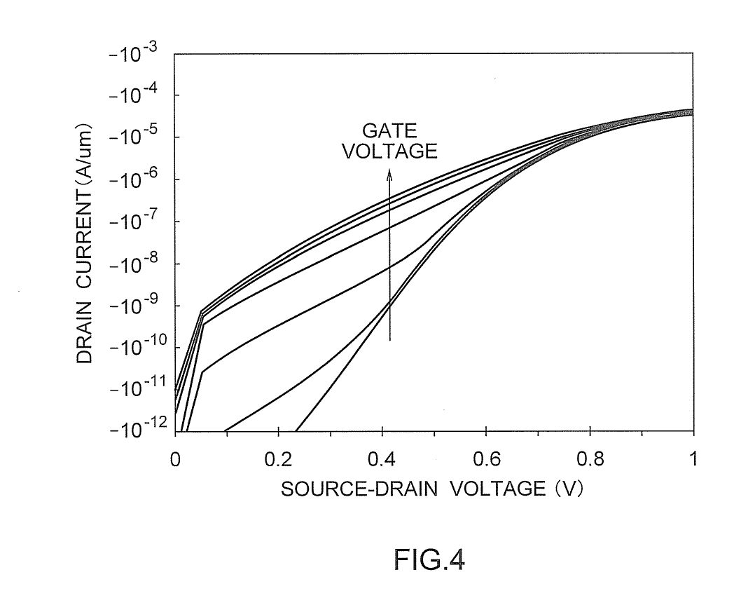

FIG. 4 is a graph for explaining operation of the first and second transfer transistors Tr_{T1} and Tr_{T2} of the first embodiment.

FIG. 4 illustrates operation of a TFET of the present embodiment in a state where a drain voltage is applied to the source terminal and a source voltage is applied to the drain terminal. Specifically, it illustrates the operation of an n-type TFET in the state where the source voltage is set to be 0 to 1 V, the drain voltage is set to be 0 V, and the gate voltage is set to be 0 to 2 V. The horizontal axis in FIG. 4 represents the source-drain voltage. The vertical axis in FIG. 4 represents the drain current. The minus signs given to the current values on the vertical axis in FIG. 4 indicate that the drain current flows in the reverse direction compared to that in normal operation.

Hereafter, the operation of the first and second transfer transistors Tr_{T1} and Tr_{T2} of the present embodiment is described with reference to FIG. 4.

The first and second transfer transistors Tr_{T1} and Tr_{T2} are sometimes used such that the current flows from the drain terminal to the source terminal, and sometimes used such that the current flows from the source terminal to the drain terminal. When the transistors Tr_{T1} and Tr_{T2} are TFETs, there is a problem whether the current can flow in both directions between the source terminal and the drain terminal.

A TFET includes source and drain regions of different conductivity types and generates the current by band-to-band tunneling between the source region and the channel region. However, when the drain voltage is applied to the source terminal of the TFET and the source voltage is applied to the drain terminal of the TFET, the band-to-band tunneling does not take place. In this case, the current by the band-to-band tunneling is not generated.

However, the TFET includes a pn junction between the source region and the channel region or between the channel region and the drain region. Therefore, when the drain voltage is applied to the source terminal of the TFET and the source voltage is applied to the drain terminal of the TFET, a diffusion current flows due to a forward voltage applied to the pn junction.

Accordingly, when the first and second transfer transistors Tr_{T1} and Tr_{T2} are TFETs, the current can flow in both directions between the source terminal and the drain terminal although the current flowing in one direction is different in characteristics from the current flowing in the other direction. FIG. 4 illustrates the operation of the n-type TFET in the state where the current flows in the reverse direction to the natural direction, that is, the current flows from the source terminal to the drain terminal.

It is noted that when the forward voltage is applied to the pn junctions of the first and second transfer transistors Tr_{T1} and Tr_{T2}, the forward voltage is also applied to the pn junctions in unselected cells. In order to suppress data readout errors, the first and second transfer transistors Tr_{T1} and Tr_{T2} of the present embodiment are therefore used within a region where the drain current varies depending on the gate voltage in FIG. 4. Specifically, the first and second transfer transistors Tr_{T1} and Tr_{T2} of the present embodiment are used in a state where the source-drain voltage in FIG. 4 is set equal to or lower than the built-in potential.

### (2) Comparative Examples of First Embodiment

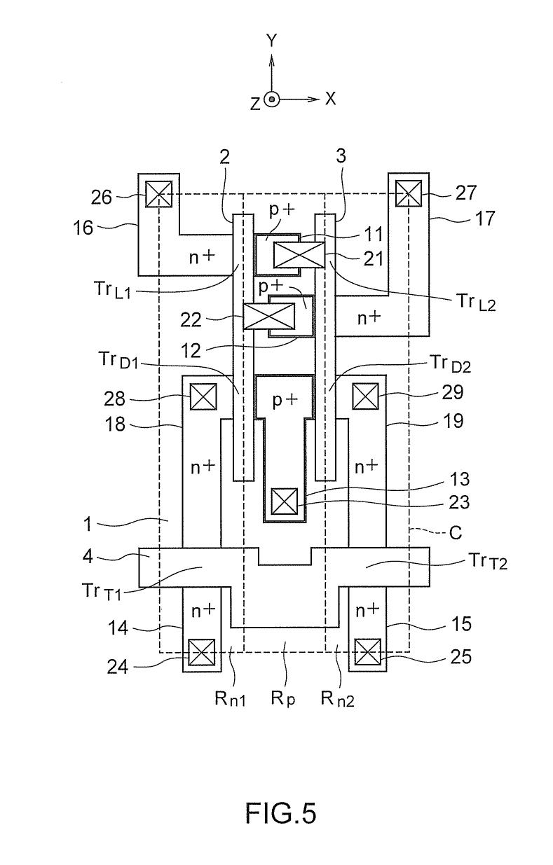

FIG. 5 is a plan view illustrating a structure of a semiconductor device of a first comparative example of the first embodiment. FIG. 5 illustrates a gate conductor layer of a SRAM cell C.

The first and second transfer transistors Tr_{T1} and Tr_{T2} are n-type MISFETs in this comparative example. Therefore, the fourth and fifth diffusion regions 14 and 15 are n-type regions in this comparative example.

Since the first and second transfer transistors Tr_{T1} and Tr_{T2} are MISFETs in this comparative example, it is difficult to suppress the short channel effect of these transistors Tr_{T1} and Tr_{T2} and to reduce power consumption of the SRAM. Moreover, since the first and second transfer transistors Tr_{T1} and Tr_{T2} are MISFETs in this comparative example, there is a problem that areas of the transistors Tr_{T1} and Tr_{T2} are large.

On the contrary, the present embodiment makes it possible, by forming the SRAM cell C with six TFETs, to reduce the power consumption of the SRAM and to reduce the areas of the first and second transfer transistors Tr_{T1} and Tr_{T2}.

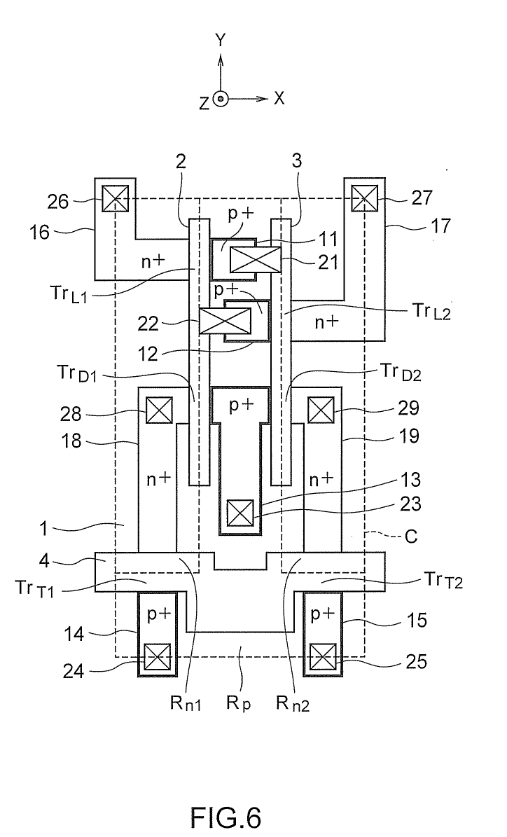

FIG. 6 is a plan view illustrating a structure of a semiconductor device of a second comparative example of the first embodiment. FIG. 6 illustrates a gate conductor layer of a SRAM cell C.

The first and second transfer transistors Tr_{T1} and Tr_{T2} of this comparative example are n-type TFETs as similar to the first embodiment. However, the layout of the SRAM cell C of this comparative example is same as the layout of the SRAM cell C of the first comparative example.

Accordingly, the first to fifth diffusion regions 11 to 15 of this comparative example are disposed not only at the center portion in the SRAM cell C but also at the end portions in the ±X-directions in the SRAM cell C. Therefore, the shape of the region Rₚ of this comparative example is not the strip shape same as that in the first embodiment but is a reverse T-shape.

In this manner, the first to ninth diffusion regions 11 to 19 corresponding to the source and drain regions are complexly disposed on the substrate 1 in this comparative example. Therefore, lithography for forming the source and drain regions may become difficult and the characteristics of the TFETs may suffer variation in this comparative example.

Meanwhile, the present embodiment makes it possible, by collectively disposing the first to fifth diffusion regions 11 to 15 at the center portion in the SRAM cell C, to simplify the layout of the p-type regions and the n-type regions corresponding to the source and drain regions. Therefore, the present embodiment makes it possible to readily perform the lithography for forming the source and drain regions and to suppress the variation in characteristics of the TFETs.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

1. A semiconductor device comprising:
a substrate;
a plurality of gate conductors disposed above the substrate and including a pair of first portions and a pair of second portions;
a first load transistor which includes source and drain regions having different conductivity types and disposed to sandwich one of the pair of first portions, wherein a diffusion region of a first conductivity type corresponding to the drain region is disposed between the pair of first portions;
a second load transistor which includes source and drain regions having different conductivity types and disposed to sandwich the other of the pair of first portions, wherein a diffusion region of the first conductivity type corresponding to the drain region is disposed between the pair of first portions;
a first driver transistor which includes source and drain regions having different conductivity types and disposed to sandwich the one of the pair of first portions, wherein a diffusion region of the first conductivity type corresponding to the source region is disposed between the pair of first portions;
a second driver transistor which includes source and drain regions having different conductivity types and disposed to sandwich the other of the pair of first portions, wherein a diffusion region of the first conductivity type corresponding to the source region is disposed between the pair of first portions;
a first transfer transistor which includes source and drain regions having different conductivity types and disposed to sandwich one of the pair of second portions, wherein a diffusion region of the first conductivity type corresponding to the source region is disposed between the pair of second portions; and
a second transfer transistor which includes source and drain regions having different conductivity types and disposed to sandwich the other of the pair of second portions, wherein a diffusion region of the first conductivity type corresponding to the source region is disposed between the pair of second portions.

2. The device of claim 1, wherein the diffusion regions of the first conductivity type of the first and second load transistors, the first and second driver transistors, and the first and second transfer transistors are disposed in a strip-shaped region extending in a first direction parallel to a surface of the substrate.

3. The device of claim 2, wherein
diffusion regions of a second conductivity type corresponding to the source or drain regions of the first load transistor, the first driver transistor and the first transfer transistor are disposed on one side of the strip-shaped region, and
diffusion regions of the second conductivity type corresponding to the source or drain regions of the second load transistor, the second driver transistor and the second transfer transistor are disposed on the other side of the strip-shaped region.

4. The device of claim 1, wherein the diffusion region of the first conductivity type of the first driver transistor shares a same diffusion region with the diffusion region of the first conductivity type of the second driver transistor.

5. The device of claim 1, wherein a diffusion region of a second conductivity type corresponding to the drain region of the first driver transistor shares a same diffusion region with a diffusion region of the second conductivity type corresponding to the drain region of the first transfer transistor.

6. The device of claim 5, wherein a diffusion region of the second conductivity type corresponding to the drain region of the second driver transistor shares a same diffusion region with a diffusion region of the second conductivity type corresponding to the drain region of the second transfer transistor.

7. The device of claim 1, wherein the diffusion region of the first conductivity type of the first transfer transistor and the diffusion region of the first conductivity type of the second transfer transistor are separate diffusion regions.

8. The device of claim 7, wherein
the pair of second portions extend in a first direction parallel to a surface of the substrate, and
the diffusion region of the first conductivity type of the first transfer transistor is disposed in the first direction of the diffusion region of the first conductivity type of the second transfer transistor.

9. The device of claim 1, wherein the diffusion region of the first conductivity type of the first load transistor and the diffusion region of the first conductivity type of the second load transistor are separate diffusion regions.

10. The device of claim 9, wherein
the pair of first portions extend in a first direction parallel to a surface of the substrate, and
the diffusion region of the first conductivity type of the first load transistor is disposed in the first direction of the diffusion region of the first conductivity type of the second load transistor.

11. The device of claim 9, further comprising:
a first contact plug disposed on the diffusion region of the first conductivity type of the first load transistor; and
a second contact plug disposed on the diffusion region of the first conductivity type of the second load transistor,
wherein the second contact plug is further disposed on the one of the pair of first portions, and the first contact plug is further disposed on the other of the pair of first portions.

12. The device of claim 1, wherein the pair of first portions and the pair of second portions extend in a first direction parallel to a surface of the substrate.

13. The device of claim 12, wherein the one of the pair of first portions and the one of the pair of second portions are disposed on a same straight line.

14. The device of claim 13, wherein the other of the pair of first portions and the other of the pair of second portions are disposed on a same straight line.

15. The device of claim 12, wherein a width between the pair of first portions is substantially equal to a width between the pair of second portions.

16. The device of claim 1, wherein the plurality of gate conductors further include a third portion electrically connected to the pair of second portions.

17. The device of claim 16, wherein
the pair of second portions extend in a first direction parallel to a surface of the substrate, and
the third portion extends in a second direction perpendicular to the first direction.

18. The device of claim 16, wherein the third portion is disposed on an opposite side to the diffusion regions of the first conductivity type of the first and second driver transistors relative to the diffusion regions of the first conductivity type of the first and second transfer transistors.

19. The device of claim 1, wherein a diffusion region of a second conductivity type corresponding to the source region of the first load transistor and a diffusion region of the second conductivity type corresponding to the source region of the second load transistor are electrically connected to a power supply line.

20. The device of claim 1, wherein the diffusion region of the first conductivity type of the first driver transistor and the diffusion region of the first conductivity type of the second driver transistor are electrically connected to a ground line.
